(19) United States
(12) Patent Application Publication
(10) Pub. No.: US 2011/0291285 A1
(43) Pub. Date: Dec. 1, 2011

(54) Semiconductor Device Comprising a Die Seal with Graded Pattern Density

(75) Inventors: Guido Ueberreiter, Dresden (DE); Matthias Lehr, Dresden (DE); Alexander Platz, Ebersbach (DE)

(73) Assignee: GLOBALFOUNDRIES INC., Grand Cayman (KY)

(21) Appl. No.: 12/964,882

(22) Filed: Dec. 10, 2010

(30) Foreign Application Priority Data
May 31, 2010 (DE) 10 2010 029 528.0

(51) Int. Cl. H01L 23/495

(52) U.S. Cl. 257/773; 257/E23.037

(57) ABSTRACT

A die seal of a semiconductor device may be provided with a varying pattern density such that a gradient between the die region and the die seal may be reduced. Consequently, for a given width of the die seal, a required mechanical stability may be achieved, while at the same time differences in topography between the die region and the die seal may be reduced, thereby contributing to superior process conditions for sophisticated lithography processes.

### BACKGROUND OF THE INVENTION

1. Field of the Invention

Generally, the present disclosure relates to the field of integrated circuits, and, more particularly, to die seal structures formed in the metallization system of semiconductor devices.

2. Description of the Related Art

Today's global market forces manufacturers of mass products to offer high quality products at a low price. It is thus important to improve yield and process efficiency to minimize production costs. This holds especially true in the field of semiconductor fabrication, since here it is essential to combine cutting edge technology with mass production techniques. It is, therefore, the goal of semiconductor manufacturers to reduce the consumption of raw materials and consumables, while at the same time improve process tool utilization, since, in modern semiconductor facilities, equipment is required which is extremely cost intensive and represents the dominant part of the total production costs. Consequently, high tool utilization in combination with a high product yield, i.e., with a high ratio of good devices to faulty devices, results in increased profitability.

Integrated circuits are typically manufactured in automated or semi-automated facilities, where the products pass through a large number of process and metrology steps to complete the devices. The number and the type of process steps and metrology steps a semiconductor device has to go through depends on the specifics of the semiconductor device to be fabricated. A usual process flow for an integrated circuit may include a plurality of photolithography steps to image a circuit pattern for a specific device layer into a resist layer, which is subsequently patterned to form a resist mask used in further processes for forming device features in the device layer under consideration by, for example, etch, implantation, deposition, polish and anneal processes and the like. Thus, layer after layer, a plurality of process steps are performed based on a specific lithographic mask set for the various layers of the specified device. For instance, a sophisticated CPU requires several hundred process steps, each of which has to be carried out within specified process margins so as to fulfill the specifications for the device under consideration.

For these reasons, a plurality of measurement data are typically obtained for controlling the production processes, such as lithography processes and the like, which may be accomplished by providing dedicated test structures, which are typically positioned in an area outside of the actual die region, which is also referred to as the frame region, which may be used for dicing the substrate when separating the individual die regions. During the complex manufacturing sequence for completing semiconductor devices, such as CPUs and the like, an immense amount of measurement data is created, for instance by inspection tools and the like, due to the large number of complex manufacturing processes whose mutual dependencies may be difficult to assess, so that usually factory targets are established for certain processes or sequences, wherein it is assumed that these target values may provide process windows so as to obtain a desired final electrical behavior of the completed devices. That is, the complex individual processes or related sequences may be monitored and controlled on the basis of respective inline measurement data such that the corresponding process results are held within the specified process margins, which in turn are determined on the basis of the final electrical performance of the product under consideration. Consequently, in view of enhanced overall process control and appropriate targeting of the various processes on the basis of the final electrical performance, electrical measurement data is created on the basis of the dedicated test structures provided in the frame region. These electrical test structures may comprise appropriate circuit elements, such as transistors, conductive lines, capacitors and the like, which are appropriately connected to corresponding probe pads so as to allow dedicated measurement strategies for assessing electrical performance of the various critical elements in the test structure.

In sophisticated semiconductor devices, not only the circuit elements formed in and above a corresponding semiconductor layer require thorough monitoring, but also the metallization system of the semiconductor device is of high complexity, thereby also requiring sophisticated process and material monitoring techniques. Due to the ongoing shrinkage of critical dimensions of the semiconductor-based circuit features, such as transistors and the like, the device features in the metallization system also have to be continuously enhanced with respect to critical dimensions and electrical performance. For example, due to the increased packing density in the device level, the electrical connections of the circuit elements, such as the transistors and the like, require a plurality of stacked metallization layers, which may include metal lines and corresponding vias in order to provide the complex wiring system of the semiconductor device under consideration. Providing a moderately high number of stacked metallization layers is associated with a plurality of process-related challenges, thereby requiring efficient monitoring and control strategies. For instance, in sophisticated applications, electrical performance in the metallization systems is typically increased by using dielectric materials having a low dielectric constant in combination with metals of high conductivity, such as copper, copper alloys and the like. Since the manufacturing process for forming metallization systems on the basis of dielectric materials of reduced permittivity, also referred to as low-k dielectrics, and highly conductive metals, such as copper, may include a plurality of very complex manufacturing steps, a continual verification of the process results is typically required in order to monitor the overall electrical performance of the metallization system and also performance of associated manufacturing strategies.

For example, the processing of copper material in a semiconductor manufacturing facility requires certain specifics with respect to obtaining metal lines and vias due to the specific characteristics of copper in view of material deposition, patterning the same and the like. That is, since copper may not be efficiently deposited on the basis of well-established chemical vapor deposition (CVD) processes and the like, and due to the fact that copper does not form volatile etch byproducts for a plurality of well-established anisotropic etch recipes, typically, a dielectric material is first deposited and patterned so as to include openings for the metal lines and vias, which are subsequently filled on the basis of a complex deposition regime, which may include the deposition of any appropriate conductive barrier material in combination with the copper bulk material that is applied on the basis of electrochemical deposition techniques. Thereafter, excess material created during the previous deposition sequence has to be removed, which is typically accomplished, at least at a certain phase of the removal process, by chemical mechanical polishing or planarization processes, thereby obtaining the desired electrically insulated metal lines that are embedded in the dielectric material. As previously indicated, the dimensions of the metal lines have to be reduced so as to comply with the increased desired packing density, thereby also requiring reduced spaces between the corresponding metal lines, which in turn necessitates the usage of low-k dielectric materials in order to maintain the parasitic RC (resistance capacitance) time constants at a desired low level, since typically signal propagation delay is significantly affected by the performance of the metallization system.

Due to the complexity of the electrical connections to be provided in the metallization system, a plurality of metallization layers are stacked on top of each other, which may, therefore, require sophisticated lithography processes so as to form a corresponding etch mask for patterning the dielectric material of the metallization layer under consideration, followed by a complex deposition regime with a final removal process sequence, during which any excess material is removed and also the resulting surface topography is enhanced in order to allow a subsequent sophisticated lithography process for patterning the dielectric material of a subsequent metallization layer. For example, the process for forming vias, i.e., vertical contact elements extending from a metal line of one metallization layer to another metal line of a neighboring metallization layer, may involve a highly critical lithography process in combination with an etch process, while also the subsequent filling in of the conductive material, such as a thin conductive barrier material, possibly in combination with a seed material, may represent critical process steps and thus have a significant influence on the overall electrical performance of the metallization layer under consideration. Furthermore, many of these complex manufacturing processes, such as lithography, etching, polishing and the like, may depend on the local neighborhood within the die region of interest in terms of the resulting process output. That is to say, the etch behavior, the deposition behavior, the polishing behavior and the like may locally depend on the pattern density, i.e., the number and size of circuit features, such as metal lines and vias provided in an appropriately selected unit area, so that certain process variations may occur with respect to device areas having a different pattern density. For example, the removal rate of device areas of moderately low pattern density, i.e., the number of device features, such as trenches, vias, gate electrodes and the like per unit area, may differ from the removal rate in areas of increased pattern density, thereby creating different height levels in device regions of significant different pattern density. The difference in height level, however, may negatively influence process results in lithography processes that are performed so as to define critical feature sizes in the corresponding device level. Since the lithography process represents the basis for obtaining critical dimensions of device features, such as transistors, metal lines, vias and the like, a corresponding difference in the critical dimensions and thus the overall performance of these device features may occur.

It is well known that great efforts are being made to steadily improve the optical properties of the lithographic system, for example in terms of numerical aperture, depth of focus and wavelength of the light source used. The resolution of an optical system is proportional to the wavelength of the light source used and to a process-related factor and is inversely proportional to the numerical aperture. For this reason, the wavelength may be reduced and/or the process-related factor may be reduced and/or the numerical aperture may be increased in an attempt to increase the overall resolution. In recent years, all three approaches have been concurrently taken, thereby resulting in highly complex lithography systems, in which the finally achieved resolution is well below the wavelength of the exposure radiation. On the other hand, the depth of focus, i.e., the range within which objects may be imaged with sufficient accuracy, is inversely proportional to the square of the numerical aperture so that recent developments in increasing the numerical aperture have resulted in a significantly reduced depth of focus, which may therefore have a significant influence on the performance of the imaging process, since corresponding topography variations may thus result in a significant modification of the final critical dimension, which in turn may lead to corresponding non-uniformities with respect to performance of, for instance, complex integrated circuits.

One source of creating significant differences in surface topography is the area between the actual die region and the frame region, in which typically a so-called die seal is provided so as to circumferentially delimit the actual die region from the frame region in which scribe lines are provided to dice the substrate when separating the individual semiconductor chips. During the dicing of the substrates, typically, significant mechanical forces may act on the neighboring die regions, which may result in damage, for instance, within the complex metallization system. As discussed above, in sophisticated semiconductor devices, typically, the metallization system may be formed on the basis of sophisticated dielectric materials having a dielectric constant of 3.0 and less, which, however, may have a significantly reduced mechanical stability compared to well-established conventional dielectric materials, such as silicon dioxide, silicon nitride and the like. Thus, upon the dicing process, the significant mechanical forces may result in the formation of cracks, material delamination events and the like, which may result in even fatal failures of the metallization system and may also contribute to a significant additional contamination of the die regions. For this reason, the die seal is provided in the metallization system of the semiconductor device so as to connect to the semiconductor substrate and provide a robust mechanical barrier in which the mechanical forces may be accommodated without causing significant damage in the metallization system within the actual die region. Typically, the die seal region may be comprised of any appropriately shaped metal features, such as line portions, vias and the like, in each of the subsequent metallization layers so as to form a robust wall or barrier, as will be described in more detail with reference to FIGS. 1a-1c.

FIG. 1a schematically illustrates a top view of a semiconductor device 100 at any manufacturing stage prior to dicing the device 100 in order to provide individual semiconductor chips. The device 100 may comprise a plurality of die or chips 110, wherein, for convenience, a single chip 110 is illustrated in FIG. 1a. It should be appreciated, however, that a plurality of such semiconductor chips or die 110 are provided as an array separated by a corresponding frame region 140 which, as previously indicated, may be used for defining appropriate scribe lines and also forming any test structures so as to not consume valuable chip area. The die or chip 110 may have any appropriate geometric configuration, for instance, as shown, a substantially square-like layout may be used, while in other cases any other rectangular layout may be used. The chip 110 comprises a die region 120, which is to be understood as any appropriate substrate material including one or more semiconductor layers and the other device levels, such as a plurality of metallization layers, which may form the wiring network for any actual circuit elements provided within the die region 120. The die region 120 may be laterally delimited by a die seal region 130, which may be understood as a plurality of densely packed metal features provided in the metallization system in order to form a mechanically stable barrier. Thus, the die seal region 130 may extend through all of the metallization layers and may also connect to a substrate material of the semiconductor device 100. Typically, the plurality of metal features in the die seal region 130 may be electrically connected and may in turn be connected to, for instance, the semiconductor material or substrate in order to enhance overall electrical robustness of any circuitry formed in the die region 120.

FIG. 1b schematically illustrates a top view of a portion of the semiconductor device 100, which is indicated as B in FIG. 1a. As illustrated, the die seal 130 may comprise seal sections 130A, 130B positioned between the die region 120 and the frame region 140, possibly with an additional buffer section 130C positioned between the sections 130A, 130B. Each of the seal sections 130A, 130B may comprise a dense structure of metallization features 131, for instance in the form of metal line portions and the like, which may interconnect with each other, thereby providing a dense “fabric” of metal-containing features, which may provide the desired superior mechanical strength. As indicated above, the metal features 131 may be formed in sophisticated dielectric materials, such as low-k dielectric materials, which per se may have a low mechanical stability. Consequently, in the die seal 130, the overall density of metal may be significantly higher compared to the die region 120 in order to compensate for the reduced mechanical stability of sophisticated low-k dielectric materials. It should be appreciated that the buffer region 130C may in other conventional designs be omitted, if considered advantageous in terms of overall stability and the like. As indicated, the die seal region 130 may define a border 130D so as to delimit the die region 120 and may also define a border 130F so as to provide a separation to the frame region 140.

It should be appreciated that the layout shown in FIG. 1b is of illustrative nature only and may represent the layout of a specific metallization layer, while the layout of an underlying layer may differ therefrom and may be appropriately connected to neighboring metallization layers on the basis of trenches, vias and the like. Typically, a width, indicated by 130W, of the die seal 130 may be defined by the lateral extension between the borders 130D and 130F and may be selected to be 5-25 μm and even more, depending on the specific requirements of a semiconductor device under consideration. That is, the stability of the metallization system as a whole may significantly depend on the number of metallization layers and the materials used therein, and thus the width 130W may be appropriately selected so as to reduce any damage during the dicing of the substrate. For example, generally, a reduced thickness of the die seal region 130 may result in a reduced mechanical stability so that, for many sophisticated semiconductor devices requiring a plurality of stacked metallization layers, for instance five metallization layers and more, on the basis of low-k dielectrics, a width of less than 5 μm may be less than desirable. On the other hand, using a width greater than 25 μm may result in undue consumption of area of the substrates since typically a plurality of semiconductor chips are provided on a single substrate and thus increasing the width of the die seal may therefore, in total, reduce the number of chips that may be placed on a single substrate.

FIG. 1c schematically illustrates a cross-sectional view of the semiconductor device 100, wherein a portion of the die region 120 and a portion of the die seal 130 is illustrated in a schematic manner. As shown, the device 100 comprises a substrate 101, such as a silicon substrate, or any other semiconductor substrate, while, in other cases, dielectric materials may be provided. Furthermore, a semiconductor layer 102, such as a silicon layer or any other appropriate semiconductor material, may be formed above the substrate 101, in and above which circuit elements 104 are provided, for instance in the form of transistors and the like. As previously explained, in sophisticated applications, at least some of the circuit elements 104 may be formed on the basis of critical dimensions of 50 nm and less. The circuit elements 104 may be embedded in the dielectric material of a contact level 103, above which is provided a metallization system 150. The metallization system 150 comprises a plurality of metallization layers, wherein, for convenience, metallization layers 151, 152 and 153 are illustrated. In each of the metallization layers 151, 152, 153, corresponding metal features 151A, 152A, 153A, respectively, are provided, for instance in the form of metal lines, vias and the like. Thus, these metal features 151A, 152A, 153A may form the wiring network for any functional circuit portions provided within the die region 120. On the other hand, in the die seal region 130, the metal features 131 are provided in accordance with any desired configuration so as to provide a desired high metal density, wherein, as previously discussed, the basic layout of the metal features 131 may differ in the various metallization layers, however, in such a manner that an appropriate connection in between the individual metal layers may be accomplished within the die seal region 130. Thus, the die seal region 130 may extend at least through the metallization system 150 and may typically connect to the semiconductor layer 102 (not shown) on the basis of appropriate contact elements provided in the contact level 103.

Typically, the metallization system 150 may be formed on the basis of manufacturing techniques and material systems as explained above. Consequently, due to the dependence of many manufacturing processes on the local pattern density, a different height level may be produced, in particular within the metallization system 150, due to the significantly increased pattern density in the die seal region 130, which may not be compensated for even by very sophisticated planarization techniques. Thus, any further complex lithography processes that have to be applied for patterning the dielectric materials of subsequent metallization layers may result in highly non-uniform process results, since typically the allowable depth of focus may be very restricted in sophisticated lithography systems, as described above, while also even a significant variation in critical dimensions may be observed within the allowable window of the depth of focus. Consequently, in addition to the difficulties in determining an appropriate depth of focus during the automated alignment procedures of the lithography systems, also the resulting critical dimensions in inner die areas and in the vicinity of the die seal 130 may vary due to the different height levels. Similarly, any test structures to be formed in the frame region may have different critical dimensions with respect to elements provided in the central area of the die region 120 and may thus reduce the authenticity of any measurement data obtained from corresponding test structures.

As discussed above, reducing the width of the die seal region 130 in order to reduce its negative influence on the overall topography of the semiconductor device may be less than desirable, since the resulting mechanical stability may not be sufficient for appropriately protecting the die region during a dicing process.

The present disclosure is directed to various devices that may avoid, or at least reduce, the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure provides semiconductor devices having a superior die seal configuration which may provide a desired high mechanical integrity of the actual die region while nevertheless reducing pronounced differences in topography, as are typically caused in conventional designs. To this end, the significant “gradient” with respect to pattern density between the die region and the die seal region may be reduced by providing a graded or varying pattern density, at least in the region between the actual die region and the die seal. That is, the overall amount of metal material in at least some of the metallization layers of the metallization system, in which the die seal is provided, may be reduced at a border separating the die seal and the actual die region. Consequently, the difference in overall pattern density between the die region and in particular between the edge region of the die and the portion of the die seal facing the actual die region may be reduced, thereby also providing a substantially graded transition in pattern density between the actual die region and the die seal. Consequently, any corresponding manufacturing processes, such as deposition, etch, planarization processes and the like, may result in a less pronounced difference in surface topography, which in turn may provide superior conditions during sophisticated lithography processes. In some illustrative embodiments disclosed herein, the pattern density may also be reduced in a portion of the die seal which faces towards the frame region, thereby also providing superior process conditions and in particular lithography conditions in the frame region, which may thus result in a reduced difference in height level between the frame region and the actual die region. Consequently, in this case, respective test structures may be provided with superior authenticity with respect to actual circuit elements in the die region, thereby also contributing to superior overall process control and device reliability.

One illustrative semiconductor device disclosed herein comprises a semiconductor layer formed above a substrate and comprising a plurality of circuit elements. The semiconductor device further comprises a metallization system formed above the semiconductor layer and comprising a plurality of metallization layers. Additionally, the semiconductor device comprises a die seal formed at least in the metallization system and delimiting a die region, wherein the die seal comprises die seal metal features in each of the plurality of metallization layers, wherein a pattern density of the die seal metal features at an inner border of the die seal is less than a pattern density at a central area of the die seal, at least in some of the plurality of metallization layers.

A further illustrative semiconductor device disclosed herein comprises a metallization system comprising a plurality of stacked metallization layers. The semiconductor device further comprises a die region and a die seal region formed in the metallization system, wherein the die seal region has an inner border delineating the die seal region from the die region. The die seal region further comprises an outer border delineating the die seal from a frame region, wherein the inner border and the outer border define a width of the die seal region. Furthermore, a ratio of metal material to dielectric material of the metallization system increases from the inner border towards the outer border, at least along a part of the die seal width.

A still further illustrative semiconductor device disclosed herein comprises a metallization system formed above a substrate. Moreover, the semiconductor device comprises a die seal formed in the metallization system and laterally delimiting a die region, wherein a pattern density of metal features of the die seal varies along a width of the die seal so as to be maximal at a central area of the die seal.

### BRIEF DESCRIPTION OF THE DRAWINGS

The disclosure may be understood by reference to the following description taken in conjunction with the accompanying drawings, in which like reference numerals identify like elements, and in which:

FIG. 1a schematically illustrates a top view of a semiconductor device comprising a semiconductor chip or die including a die region that is laterally delineated by a die seal formed in a metallization system;

FIG. 1b schematically illustrates an enlarged top view of a portion of the semiconductor device of FIG. 1a, wherein a complex pattern of metal features of the die seal is illustrated, according to conventional designs;

FIG. 1c schematically illustrates a cross-sectional view of the semiconductor device, i.e., of the die region and the die seal region, according to conventional configurations;

FIG. 2a schematically illustrates a top view of a portion of a metallization layer of a metallization system, wherein a pattern density or a ratio of metal material to dielectric material may be determined in accordance with principles disclosed herein;

FIG. 2b schematically illustrates a top view of a semiconductor device comprising a semiconductor chip with a die region and a die seal having a graded pattern density which increases, starting from a border separating the die region and the die seal, along at least a portion of a width of the die seal, according to illustrative embodiments;

FIG. 2c schematically illustrates an enlarged view of a layout or an actual implementation of one of the plurality of metallization layers in the die seal region having a varying pattern density as shown in FIG. 2b;

FIG. 2d schematically illustrates a top view of a semiconductor device in which the pattern density of a die seal may be reduced at an inner border and an outer border of the die seal, according to further illustrative embodiments;

FIG. 2e schematically illustrates an enlarged top view of a layout or an actual implementation of one of the metallization layers having the varying pattern density of FIG. 2d; and

FIG. 2f schematically illustrates a cross-sectional view of a semiconductor device in which a varying pattern density of metal features in one or more metallization layers of a die seal may be provided, according to still further illustrative embodiments.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

The present disclosure provides semiconductor devices in which a die seal is provided in the metallization system, wherein a width of the die seal may be selected so as to comply with requirements in terms of mechanical stability without unduly consuming valuable substrate area, while at the same time process-related topography differences may be reduced. For this purpose, the pattern density in the die seal may be appropriately varied, at least in some metallization layers, in order to reduce the gradient in pattern density, i.e., the difference in pattern density, between the die region and the die seal. As previously explained, typically, a relatively high density of metal features is to be provided in the die seal in order to provide the required mechanical stability for a given width of the die seal and for a given configuration of the metallization system under consideration. It has been recognized that the mechanical stability may be preserved in the metallization systems for an acceptable width of the die seal, while, on the other hand, the density of metal features may be varied so as to obtain a “milder” transition from the pattern density within the die region to a maximum desired pattern density within the die seal. That is, the transition from an average pattern density in the die region of complex semiconductor devices to the moderately high density within a die seal region may be extended over several micrometers, i.e., at least a significant portion of the width of the die seal, thereby also reducing the effects of the difference in pattern density for corresponding manufacturing processes, as is also described above. Thus, the difference in height level, which may conventionally be increasingly caused upon forming a complex metallization system, may be significantly reduced, thereby providing superior lithography conditions, for instance for adjusting an appropriate depth of focus and the like.

In some illustrative embodiments disclosed herein, a reduced pattern density may also be provided at the boundary between the die seal and the frame region, thereby also contributing to an overall superior surface topography. In this case, a maximum pattern density may be provided in a central area of the die seal, which may thus contribute to the desired high mechanical stability, wherein the degree of mechanical stability may increase from the outer border towards the central region, thereby also efficiently protecting the die region during critical processes, such as dicing the substrate.

In some illustrative embodiments, the varying pattern density of metal features may be provided in every metallization layer of the metallization system, while in other embodiments the variation in pattern density may be restricted to certain metallization layers, which are considered particularly critical in terms of creating a pronounced surface topography.

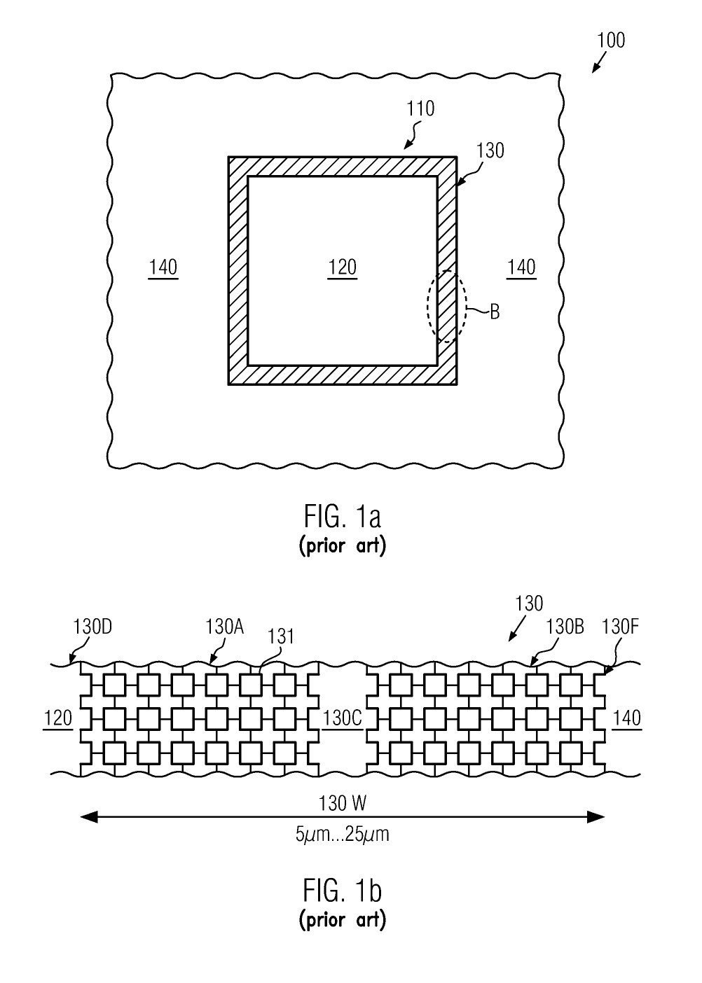

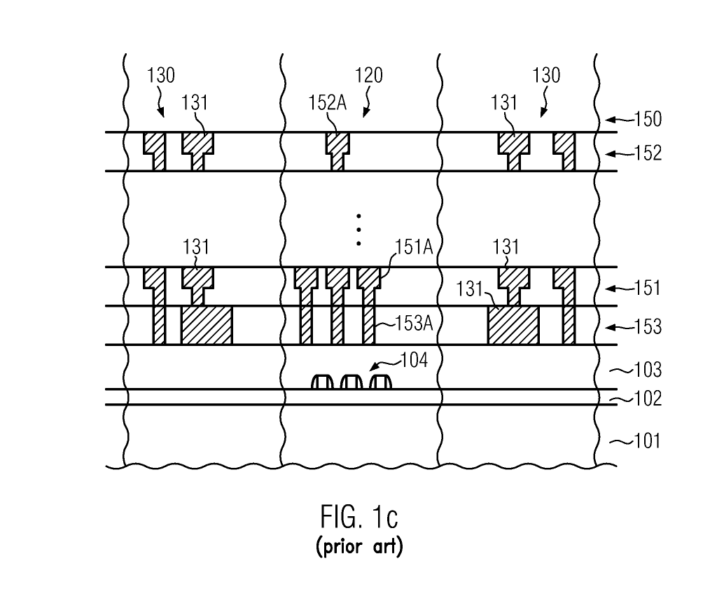

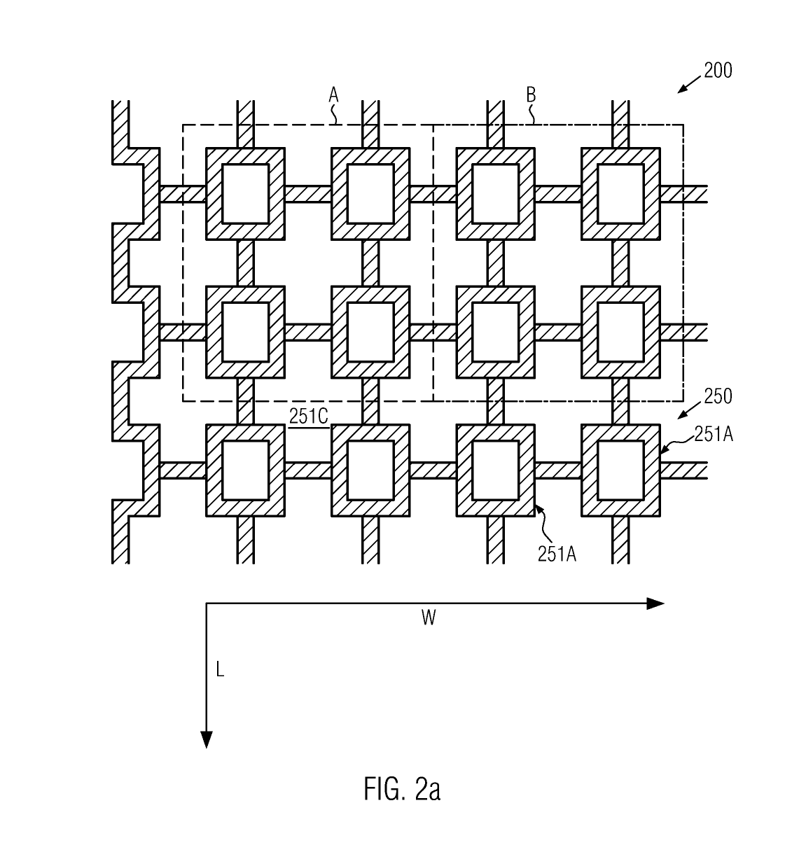

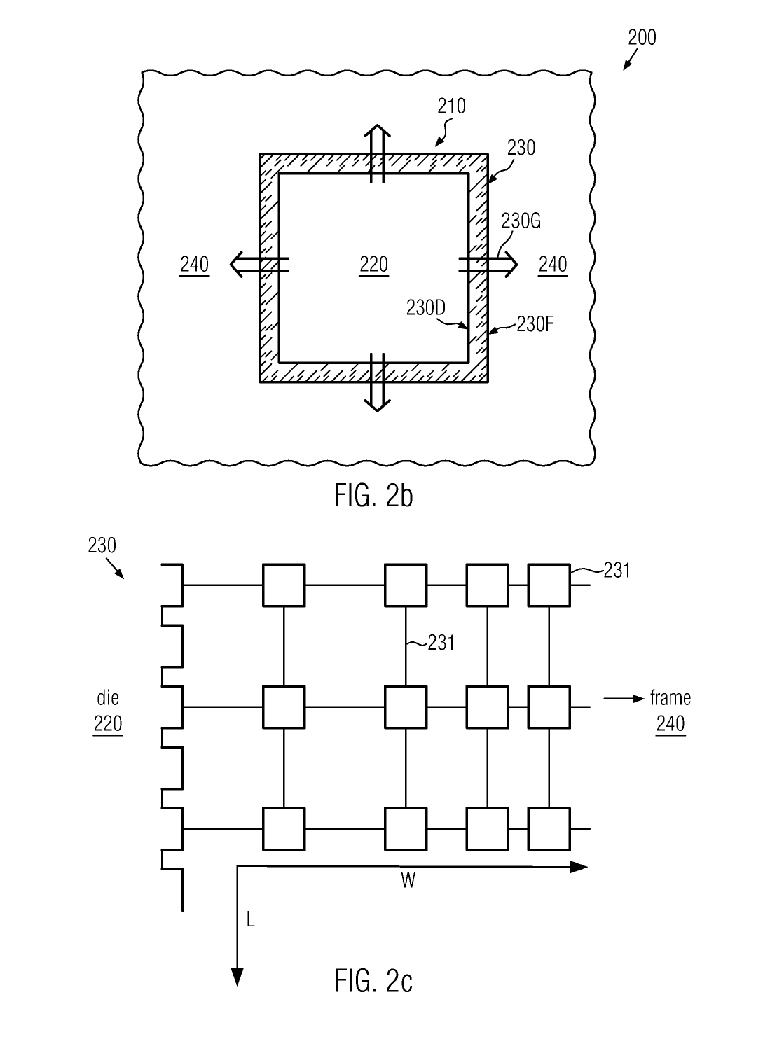

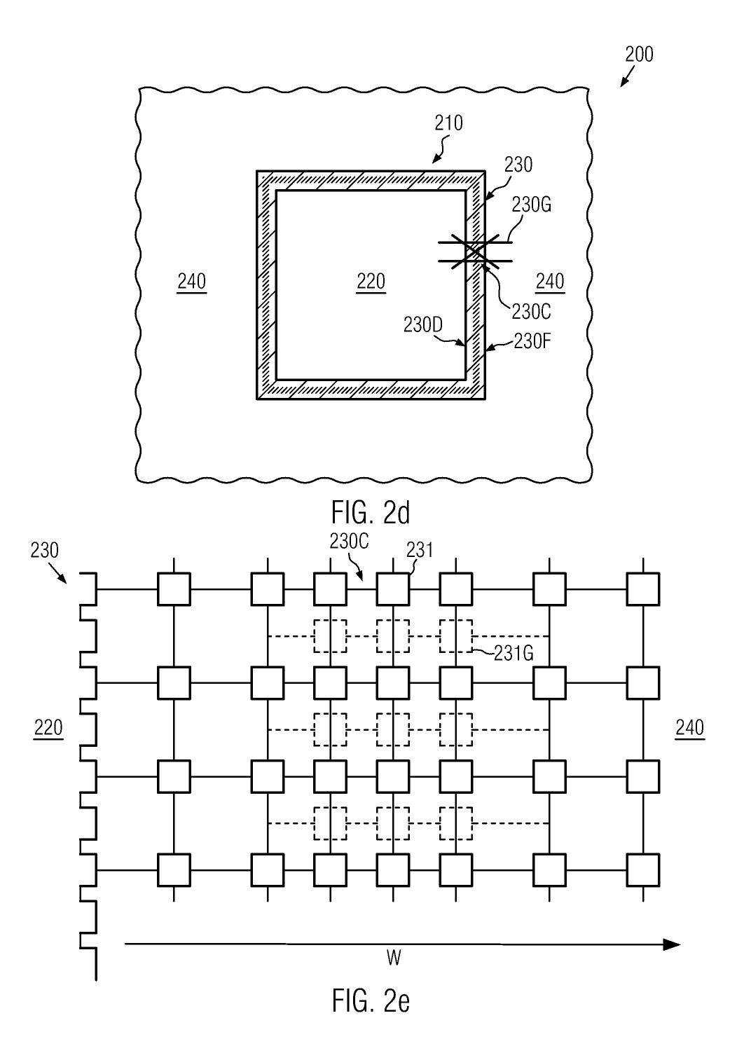

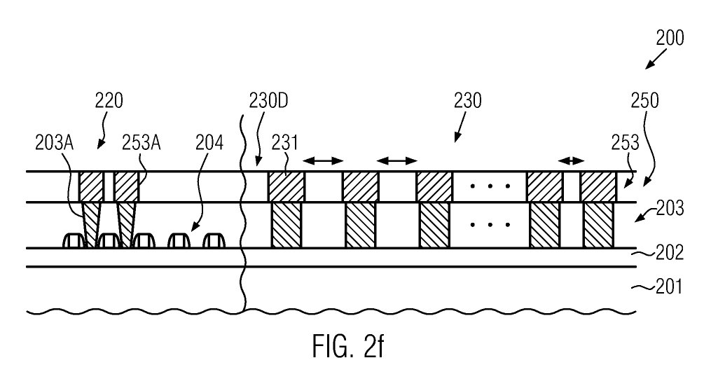

With reference to FIGS. 2a-2f, further illustrative embodiments will now be described in more detail, wherein reference may also be made to FIGS. 1a-1c, if appropriate.

FIG. 2a schematically illustrates a top view of a portion of a semiconductor device 200 which may comprise a metallization system 250. The metallization system 250 may typically comprise a plurality of stacked metallization layers, wherein, for convenience, one of these metallization layers is illustrated in FIG. 2a. The portion of the metallization system 250 may represent any device region, such as a die seal region and the like, as will be described later on in more detail. In other cases, the portion shown in FIG. 2a may represent a die region and the like. In the example shown, the metallization system 250 may comprise a plurality of metal features 251A, for instance in the form of metal line portions and the like. The metal features 251A may be embedded in a dielectric material 251C, such as a low-k dielectric material and the like, as previously explained. The metal features 251A may be provided on the basis of a specific “pattern density,” which may vary significantly in a die region according to the corresponding required layout for providing a local conductive wiring network for any circuit elements of the semiconductor device 200. In the present application, the term ‘pattern density’ may be expressed in a quantitative manner by specifying the amount of metal provided within a “unit” area when the term “density” is to be understood as an area density. In other cases, the amount of metal within a unit volume may be determined so as to specify the pattern density, for instance in the metallization system 250 as a whole, or within individual metallization layers, wherein, however, in this case, the selection of a unit volume has to be restricted to a specific metallization level. Another appropriate metric for the pattern density represents the ratio of metal material to dielectric material, for instance at the surface of a specified metallization layer, so that a corresponding ratio of metal material to dielectric material may be readily determined locally within each individual metallization layer. For example, in illustrative embodiments, respective unit areas as, for example, represented by areas A and B, may be defined such that the size thereof is sufficiently small so as to reliably detect a variation of an average metal fraction in surface areas A and B, while, however, the size is large enough in order to provide an appropriate average content of metal. For example, a unit area in the form of a square having a side length of approximately 500 nm-2 μm may be appropriate for assessing the pattern density in a die seal, which may typically have a width of several μm to several tenths of μm. Thus, by selecting unit areas with the above-specified size, a variation in pattern density may be readily detected. For example, when defining a plurality of adjacent unit areas, such as the areas A and B, the pattern density in each of these areas may be determined, for instance, by determining the amount of metal, the ratio of metal material to dielectric material and the like, and thus also any difference in the pattern density may be determined, for instance along a width direction, as indicated by W. It should be appreciated that the position of the unit areas A and B along a length direction, as indicated by L, may not affect quantitative determination of a variation in pattern density, as long as the unit areas are placed at the same position with respect to the length direction.

FIG. 2b schematically illustrates a top view of a semiconductor device 200 comprising a semiconductor chip or die 210 formed adjacent to a frame region 240 and comprising a die region 220 that is laterally delimited by a die seal 230. As explained above with reference to the semiconductor device 100, the die seal 230 may be formed in a metallization system of the device 200 and may comprise any appropriate network of metal features in order to achieve a desired superior mechanical stability, as is also previously explained. The die seal 230 may thus comprise an inner border 230D separating the die region 220 and the die seal 230. Similarly, an outer border 230F may separate the die seal 230 from the frame region 240. Typically, for each of the various metallization layers of the metallization system (not shown), the average pattern density in the die region 220 may be less than the corresponding pattern density in the die seal 230. According to the principles disclosed herein, however, the die seal 230 may have a reduced pattern density at the inner border 230D, which may increase towards the outer border 230F. Consequently, a maximum pattern density within the die seal 230 may be reached with a certain offset from the inner border 230D, thereby also significantly reducing a “gradient” 230G in pattern density between the die region 220 and the die seal 230.

FIG. 2c schematically illustrates an enlarged view of a portion of the die seal 230. As illustrated, metal features 231 may be provided so as to obtain a varying pattern density along at least a portion of the width direction, indicated by W, from the die region 220 towards the frame region 240. For example, any basic metal features, such as square-like elements and the like, may be used in combination with metal line portions, wherein the lateral offset, at least in one direction, may be reduced in order to increase the overall pattern density. It should be appreciated, however, that any other configuration may be used in order to increase the ratio of metal to dielectric material in the die seal 230 towards the frame region 240. It should be appreciated that the portion of the die seal 230 as illustrated in FIG. 2c may represent any metallization layer in the corresponding metallization system, wherein each metallization layer may not necessarily have a varying metal density.

FIG. 2d schematically illustrates a top view of the semiconductor device 200 according to further illustrative embodiments in which a transition of superior smoothness may be achieved with respect to the die region 220 and the die seal 230 on the one hand, and also between the die seal 230 and the frame region 240. To this end, the pattern density in the die seal 230 at the inner border 230D may be reduced and may increase towards a central area 230C. Similarly, the metal density at the outer border 230F may be reduced and may increase towards the central region 230C, as indicated by 230G. Consequently, in the embodiment shown, a maximum pattern density may be established in the central area 230C, which may have a width of approximately 1-3 μm when the total width of the die seal 230 may be 5-10 μm. In other cases, when the total width may be in the range from approximately 10-25 μm, a width of the central area 230C may range from 5-15 μm. It should be appreciated that a substantially constant and high pattern density may be provided in the central area 230C, thereby providing high mechanical stability, while, on the other hand, the increase of pattern density from the frame region 230F towards the central area 230C may efficiently accommodate any mechanical forces, which may typically occur during the dicing of the substrate of the device 200. Thus, a pronounced buffer region, as for instance shown in FIG. 1b for the device 100, may no longer be required. Instead, a varying pattern density may be implemented wherein, in total, the amount of metal within the die seal 230 may be comparable with the total amount of metal in the die seal 130 of FIG. 1b for otherwise identical conditions, for instance in terms of the metallization system and the lateral dimensions of the die seals.

FIG. 2e schematically illustrates an enlarged top view of the die seal 230, i.e., of any of the metallization layers in which the die seal 230 may be formed. As illustrated, a significantly increased pattern density may be obtained in the central area 230C, for instance by reducing the lateral distance between the basic metal features 231, for instance in one lateral direction, as indicated by the solid lines, while, in other cases, the lateral distance of the metal features in both lateral directions may be reduced, as indicated by the additional metal features 231G shown in dashed lines. It should be appreciated, however, that the metal features 231, 231G are of illustrative nature only and any other metal features, such as metal line portions having any appropriate configuration, vias and the like, may be provided so as to obtain the desired variation in pattern density. Furthermore, as also discussed above, the variation in pattern density may be provided in at least some of the metallization layers, while in other cases each metallization layer may have a varying pattern density in metal features.

FIG. 2f schematically illustrates a cross-sectional view of the device 200 according to illustrative embodiments. As illustrated, the device 200 may comprise a substrate 201 in combination with a semiconductor layer 202, in and above which may be provided a plurality of circuit elements 204, such as field effect transistors, resistors, capacitors and the like. The circuit elements 204 may be formed on the basis of critical dimensions of 50 nm and less, thereby requiring sophisticated manufacturing strategies, for instance in terms of lithography processes, etch processes, deposition processes, planarization processes and the like. Moreover, a contact level 203 may be provided so as to passivate the circuit elements 204 and provide contact elements 203A, which may connect the circuit elements 204 to a metallization system 250, which may comprise a plurality of metallization layers, wherein, for convenience, a single metallization layer 253 is illustrated in FIG. 2f. However, as explained above with reference to the device 100, in complex semiconductor devices, typically, a plurality of metallization layers, for instance five metallization layers and more, may be implemented. As shown, in the die region 220, metal features 253A may be provided so as to correspond to the layout requirements for the circuit elements 204 and thus to connect to the contact elements 203A. On the other hand, in the die seal 230, the metal features 231 may be provided so as to provide the desired high metal density in order to achieve a superior mechanical stability, in particular for metallization systems comprising sophisticated and thus sensitive low-k dielectric materials. As explained above, the metal features 231, however, may be provided so as to achieve a reduced pattern density, at least at the inner border 230D, in order to avoid undue surface topography differences between the die region 220 and the die seal 230. For example, as illustrated in FIG. 2f, the lateral distance between adjacent features 231 may be reduced along the width direction of the die seal 230, as is also previously explained, when a standard lateral size of the features 231 is to be provided. In other cases, for a given pitch of metal features and spaces, the size of the metal portion of a corresponding component may be increased in order to obtain the increasing metal density, as required. It should be appreciated that further metallization layers may be formed above the layer 253, wherein, at least in some of these layers, a similar varied pattern density of the metal features 231 may be implemented so that, in total, the metal density may also vary.

The semiconductor device 200 as illustrated in FIGS. 2a-2f may be formed on the basis of any appropriate manufacturing technique, as is, for instance, also described with reference to the device 100, wherein, however, appropriate lithography masks may be applied during the formation of the contact level and also possibly the device level 202 in order to appropriately connect to the metallization system 250, in which metal features 231, 231G may be provided so as to obtain the desired varying pattern density. As discussed above, critical process steps, such as deposition processes, planarization processes, etch processes and the like, which may exhibit a significant degree of pattern density dependent behavior, may result in a less pronounced difference between the die region and the die seal, thereby also contributing to superior conditions during sophisticated lithography processes to be used in forming the metallization system 250.

As a result, the present disclosure provides semiconductor devices in which a transition of superior “smoothness” in pattern density between a die region and a die seal may be achieved by implementing a varying pattern density in the die seal region which may, starting from the die region border, increase towards at least a portion of the width of the die seal. In some illustrative embodiments, a reduced pattern density in the die seal may also be implemented at the border formed between the die seal and the frame region, thereby also contributing to superior process conditions during critical pattern density dependent process steps. On the other hand, a required high metal density may still be provided, for instance, in a central area of the die seal, thereby achieving a desired high mechanical stability, for instance, for a die seal width of 5-25 μm, without unduly consuming valuable chip area.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A semiconductor device, comprising:
a semiconductor layer formed above a substrate and comprising a plurality of circuit elements;
a metallization system formed above said semiconductor layer, said metallization system comprising a plurality of metallization layers; and
a die seal formed at least in said metallization system and delimiting a die region, said die seal comprising die seal metal features in each of said plurality of metallization layers, a pattern density of said die seal metal features at an inner border of said die seal being less than a pattern density at a central area of said die seal, at least in some of said plurality of metallization layers.

2. The semiconductor device of claim 1, wherein said pattern density of said die seal metal features at an inner border of said die seal is less than a pattern density at a central area of said die seal in each metallization layer of said metallization system.

3. The semiconductor device of claim 1, wherein said pattern density of said die seal metal features increases from said inner border to an outer border of said die seal.

4. The semiconductor device of claim 1, wherein said pattern density of said die seal metal features at an outer border of said die seal is less than said pattern density at said central area of said die seal in said at least some of said plurality of metallization layers.

5. The semiconductor device of claim 4, wherein said pattern density of said die seal metal features at an outer border of said die seal is less than said pattern density at said central area of said die seal in each metallization layer of said metallization system.

6. The semiconductor device of claim 1, wherein a width of said die seal from said inner border to an outer border is in the range of 5-25 μm.

7. The semiconductor device of claim 1, wherein said metallization system comprises five or more metallization layers.

8. The semiconductor device of claim 1, wherein said pattern density of said die seal metal features at an inner border of said die seal is greater than the pattern density at said central area of said die seal in a subset of said plurality of metallization layers other than some metallization layers.

9. A semiconductor device, comprising:
a metallization system comprising a plurality of stacked metallization layers; and
a die region and a die seal region formed in said metallization system, said die seal region having an inner border delineating said die seal region from said die region, said die seal region further having an outer border delineating said die seal from a frame region, said inner border and said outer border defining a width of said die seal region;
wherein a ratio of metal material to dielectric material of said metallization system increases from said inner border towards said outer border at least along a part of said die seal width.

10. The semiconductor device of claim 9, wherein a ratio of metal material to dielectric material increases from said inner border towards said outer border at least along a part of said die seal width for each of said plurality of metallization layers.

11. The semiconductor device of claim 9, wherein said ratio of metal material to dielectric material decreases towards said outer border at least along a part of said die seal width.

12. The semiconductor device of claim 11, wherein a ratio of metal material to dielectric material decreases towards said outer border at least along a part of said die seal width for each of said plurality of metallization layers.

13. The semiconductor device of claim 9, wherein said ratio increases along a first part of the width and remains substantially constant towards said outer border.

14. The semiconductor device of claim 9, wherein said ratio in a central area of said die seal region is less than said ratio at said outer border.

15. The semiconductor device of claim 9, wherein said width is substantially constant and is selected from a range of 5-25 μm.

16. The semiconductor device of claim 9, wherein a maximum ratio of metal material to dielectric material in said die region is less than a minimum ratio in said die seal region.

17. The semiconductor device of claim 9, wherein said metallization system comprises five or more metallization layers.

18. The semiconductor device of claim 9, wherein said die region comprises circuit elements with critical dimensions of 50 nm or less.

19. A semiconductor device, comprising:
a metallization system formed above a substrate; and
a die seal formed in said metallization system and laterally delimiting a die region, a pattern density of metal features of said die seal varying along a width of said die seal so as to be maximal at a central area of said die seal.

20. The semiconductor device of claim 19, wherein said width is substantially constant along said die seal and is selected from the range of 5-25 μm.
